(19) United States
(12) Patent Application Publication
(10) Pub. No.: US 2026/0265149 A1
(43) Pub. Date: Sep. 10, 2026

(54) THERMOELECTRIC MATERIALS WITH NETWORKED HETEROSTRUCTURES PROVIDING ENHANCED THERMOELECTRIC EFFICIENCY AND PREPARATION METHOD THEREOF

(71) Applicant: CHAIRMAN, DEFENCE RESEARCH & DEVELOPMENT ORGANISATION, New Delhi (IN)

(72) Inventor: Jasa RAM, Jodhpur (IN)

(21) Appl. No.: 19/164,320

(22) PCT Filed: Nov. 24, 2023
(86) PCT No.: PCT/IN2023/051089

§ 371 Date: Sep. 11, 2025

(30) Foreign Application Priority Data
Mar. 14, 2023 (IN) 202311017134

(51) Int. Cl. C04B 35/515; C04B 35/626; C04B 35/64; C04B 35/653; H10N 10/01; H10N 10/852

(52) U.S. Cl. CPC C04B 35/515; C04B 35/6262; C04B 35/64; C04B 35/653; H10N 10/01; H10N 10/852; C04B 2235/38; C04B 2235/40

(57) ABSTRACT

A facile and scalable method for preparation of networked heterostructures in thermoelectric materials at nano-scale is disclosed. The preparation method involves rocking the melted form of component B with nanomaterial of component A under inert environment, followed by controlled consolidation. Honeycomb like network of component B having filled-in voids by component A forms heterostructure B/A at nano-scale, where component A and B can be metal, semiconductor or insulator. The method of thermoelectric figure of merit (ZT) enhancement by quantum confinement effects and its polarity reversal by carrier injection from barrier layer in nano-sized heterostructures are also disclosed. ZT>2 in both p-type and n-type metal-semiconductor bulk heterostructures of formula D_{δ}/BiₓSb₂₋ₓD_{y}M_{3-y} are demonstrated. The method of ZT enhancement is also applicable to semiconductor-semiconductor heterostructures as well as superlattice structures. High ZT materials find usages in power generation, Peltier cooling and refrigeration, thermal infrared sensing and imaging, and thermal infrared display.

### FIELD OF THE INVENTION

The present invention relates to thermoelectric materials and, more particularly, to development and efficiency enhancement methods of thermoelectric materials.

### BACKGROUND OF THE INVENTION

Pure metals in their bulk form are not considered as suitable candidate for thermoelectric purposes due to negligible difference in their chemical potential values. Initially, intermetallic materials, such as nickel-chromium, nickel aluminium, platinum-rhodium, constantan etc, were used as thermoelectric materials, particularly for temperature measurement thermocouples. Their application portfolio remained limited due to poor thermoelectric efficiency.

With advancement in technology, highly doped semi-conductors found their place with capability to produce n-type and p-type thermoelectric phenomena occurring by shift of Fermi-level (Chemical Potential in metals) due to change in type of doping. The efficiency of semiconductor thermoelectric materials is much better than intermetallic alloys due to band-gap values governing operating temperature, contrasting positions of Fermi-level between p-type and n-type materials forming thermoelectric couple, instead of forming couple with Seebeck coefficient reference copper and reduced lattice thermal conductivity values.

Most of the research and development efforts eventually shifted to semiconductors as potential thermoelectric materials. Bismuth-antimony chalcogenides were established as suitable thermoelectric materials above room temperature application due to favourable constituent governing parameter.

Thermoelectric efficiency parameter for any material is established as figure of merit (ZT), which is defined as ZT=(S²σ/κ) T, where S is Seebeck Coefficient, σ is electrical conductivity, κ is thermal conductivity and T is absolute temperature. Thus, Z is determined by ratio of power factor (PF) and κ, where power factor is defined as PF=S²σ. The value of ZT remained around one for many decades, until theoretical predictions about ZT enhancement by quantum confinement in prior art {L. D. Hicks and M. S. Dresselhause, “Thermoelectric figure of merit of a one-dimensional conductor” Phys. Rev. B 47, 16631 (1993) and “Effect of quantum-well structures on thermoelectric figure of merit” Phys. Rev. B 47, 12727(1993)} brought resurge in research and development.

Experimental reports for realization of the ZT enhancement by quantum confinement are limited to quantum wells {L. D. Hicks et. al., “Experimental study of the effect of quantum-well structure on thermoelectric figure of merit” Phys. Rev. B 53, R10493 (1996); U.S. Pat. No. 7,400,050 B2}, quantum wires {J. Heremans and C. M. Thrush, “Thermoelectric power of bismuth nanowires” Phys. Rev. 59, 12579 (1999); Yu-Ming Lin et al, “Transport properties of Bi nanowire array” Appl. Phys. Lett. 76, 3944 (2000); Yu-Ming Lin et al, “Semimetal-semiconductor transition in Bi₁₋ₓSbₓ alloy nanowires and their thermoelectric properties” Appl. Phys. Lett. 81, 2403 (2002); Patent Publication No. US 2014/0024202 A1}, and superlattices {T. C. Harman et al, “Quantum dot superlattice thermoelectric materials and devices” Science 297, 2229 (2002); Hiromichi Ohta et al, “Giant thermoelectric Seebeck coefficient of a two-dimensional electron gas in SrTiO₃” Nat. Mat. 6, 129 (2007); J. C. Caylor et al, “Developing PbTe-based superlattice structures with enhanced thermoelectric performance” IEEE ICT, 492 (2005); S. Ghamaty et al, “Quantum well thermoelectric devices and applications” IEEE ICT 563 (2003); Patent Publication No. US 2011/0062420 A1; Patent Publication No. US 2007/0084499 A1; U.S. Pat. No. 5,550,387 dated 27 Aug. 1996; U.S. Pat. No. 5,436,467 dated 25 Jul. 1995; U.S. Pat. No. 9,136,456 B2; U.S. Pat. No. 7,400,050 B2; U.S. Pat. No. 8,569,710 B2; PCT Patent International Publication No. WO 03/096438 A2; PCT Patent International Publication No. WO 01/17035 A1; PCT Patent International Publication No. WO 98/42033; PCT Patent International Publication No. WO 98/42034}. These structures require complicated and costly techniques, such as Molecular Beam Epitaxy (MBE) for their development.

### OBJECTIVE OF THE INVENTION

An object of the present disclosure is to provide easily scalable method for obtaining thermoelectric heterostructure materials having nano-sized heterostructures in honeycomb like networked morphology at nano-scale, in bulk synthesis.

Another object of the present disclosure is to realize both p-type and n-type thermoelectric heterostructure materials by same process.

Yet another object of the present disclosure is to obtain thermoelectric heterostructure materials with enhanced thermoelectric efficiency.

Yet another object of the present disclosure is to provide thermoelectric heterostructure materials with enhanced Seebeck coefficient, increased electrical conductivity, reduced thermal conductivity, and enhanced figure of merit.

### SUMMARY OF THE INVENTION

According to an embodiment, a method for obtaining networked heterostructure nanomaterial by synthesis is disclosed. The method includes mixing nanomaterial powder of a component A with powder of a component B in a ratio selected from a range of 95:05 to 75:25 to obtain a mixture thereof. The method further includes heating the obtained mixture to melt the component B in the mixture under vacuum while simultaneously rocking the mixture during heating. The method further includes quenching the heated mixture in air to obtain a quenched mixture. The method further includes grinding the quenched mixture containing components A and B into a powdered form of the quenched mixture. The method further includes filling the powdered form of the quenched mixture into a predesigned die. The method further includes consolidating the powdered form of the quenched mixture by sintering in an evacuated chamber to obtain the networked heterostructure nanomaterial.

According to an embodiment, a heterostructure thermoelectric nanomaterial is disclosed. The heterostructure thermoelectric nanomaterial includes heterostructure of formula BiₓSb₂₋ₓD_{y}M_{3-y}/D_{δ}, wherein BiₓSb₂₋ₓD_{y}M_{3-y} is component A and D is component B, wherein elements D and M are selected from group of Te, Se, S; wherein value of x, y, and δ is in the range of 0 to 3.

In an embodiment, nanostructure of the heterostructure thermoelectric nanomaterial forms networked heterostructure morphology at nanoscale of range 1-10 nm, wherein component B has honeycomb like networked structure with voids therebetween and wherein the voids are filled with component A.

In an embodiment, the concept of enhancement in thermoelectric efficiency of the networked heterostructure comprising of: quantum confinement in metallic or semiconducting layers of component B, band offset for quantum confinement obtained by semiconducting thermoelectric nanomaterial barrier layers of component A, and carrier injection from barrier layer of component A into quantum well layer of component B to obtain different polarity thermoelectric heterostructure.

In an embodiment, a maximum value of Figure of Merit (ZT) is 2.1 around room temperature for the p-type tellurium/Sb₂₋ₓBiₓTe₃ heterostructure.

In an embodiment, a maximum value of Figure of Merit (ZT) is 2.6 around room temperature for the n-type tellurium/Bi₂Te₃₋ₓSeₓ heterostructure.

### BRIEF DESCRIPTION OF DRAWINGS

For a more complete understanding of example embodiments of the present technology, reference is now made to the following descriptions taken in connection with the accompanying drawings in which:

FIG. 1 illustrates a flow chart of the method, in accordance with an exemplary embodiment of the present disclosure.

FIG. 2 illustrates photographs of consolidated pellets of the heterostructures.

FIG. 3 illustrates High Resolution—Transmission Electron Microscopy (HR-TEM) image of heterostructure sample at 100 nm scale showing honeycomb like network of component B and voids filled with component A, according to an embodiment of the present disclosure.

FIG. 4 illustrates HR-TEM image of heterostructure sample at 50 nm scale showing honeycomb like network of component B and voids filled with component A, according to an embodiment of the present disclosure.

FIG. 5 illustrates HR-TEM image of heterostructure sample at 5 nm scale showing few quintuple layers of component B and few atomic layers of component B, according to an embodiment of the present disclosure.

FIG. 6 illustrates HR-TEM image of heterostructure sample at 5 nm scale showing few quintuple layers of component B and few atomic layers of component B at another location in the image, according to an embodiment of the present disclosure.

FIG. 7 illustrates a graphical representation of measured Seebeck coefficient(S) of Te_{δ}/BiₓSb₂₋ₓTe₃ heterostructure as function of temperature for different values of δ, according to an embodiment of the present disclosure.

FIG. 8 illustrates a graphical representation of measured electrical conductivity (σ) of Te_{δ}/BiₓSb₂₋ₓTe₃ heterostructure as function of temperature for different values of 8, according to an embodiment of the present disclosure.

FIG. 9 illustrates a graphical representation of calculated values of power factor (S²σ) from the measured values of S and σ of Te_{δ}/BiₓSb₂₋ₓTe₃ heterostructure as function of temperature for different values of δ, according to an embodiment of the present disclosure.

FIG. 10 illustrates a graphical representation of measured thermal diffusivity of Te_{δ}/BiₓSb₂₋ₓTe₃ heterostructure as function of temperature for different values of δ, according to an embodiment of the present disclosure.

FIG. 11 illustrates a graphical representation of calculated values of thermal conductivity from the measured values of thermal diffusivity, specific heat and solid density of Te_{δ}/BiₓSb₂₋ₓTe₃ heterostructure as function of temperature for different values of δ, according to an embodiment of the present disclosure.

FIG. 12 illustrates a graphical representation of calculated values of figure of merit from the calculated values of power factor and thermal conductivity of Te_{δ}/BiₓSb₂₋ₓTe₃ heterostructure as function of temperature for different values of δ, according to an embodiment of the present disclosure.

FIG. 13 illustrates a graphical representation of Temperature dependent (a) Hall mobility and (b) carrier concentration for optimum performance compositions of p-type Te_{δ}/BiₓSb₂₋ₓTe₃ heterostructures, according to an embodiment of the present disclosure.

FIGS. 14(a) and (b) illustrates a graphical representation of measured Hall resistance and longitudinal resistance of Te_{δ}/BiₓSb₂₋ₓTe₃ heterostructure as function of applied magnetic field at room temperature, according to an embodiment of the present disclosure.

FIG. 15 illustrates a graphical representation of measured Seebeck coefficient(S) of Te_{δ}/Bi₂Te_{3-y}Se_{y} heterostructure as function of temperature for different values of δ, according to an embodiment of the present disclosure.

FIG. 16 illustrates a graphical representation of measured electrical conductivity (σ) of Te_{δ}/Bi₂Te_{3-y}Se_{y} heterostructure as function of temperature for different values of δ, according to an embodiment of the present disclosure.

FIG. 17 illustrates a graphical representation of calculated values of power factor (S²σ) from the measured values of S and σ of Te_{δ}/Bi₂Te_{3-y}Se_{y} heterostructure as function of temperature for different values of δ, according to an embodiment of the present disclosure.

FIG. 18 illustrates a graphical representation of measured thermal diffusivity of Te_{δ}/Bi₂Te_{3-y}Se_{y} heterostructure as function of temperature for different values of δ, according to an embodiment of the present disclosure.

FIG. 19 illustrates a graphical representation of calculated values of thermal conductivity from the measured values of thermal diffusivity, specific heat and solid density of Te_{δ}/Bi₂Te_{3-y}Se_{y} heterostructure as function of temperature for different values of δ, according to an embodiment of the present disclosure.

FIG. 20 illustrates a graphical representation of calculated values of figure of merit from the calculated values of power factor and thermal conductivity of Te_{δ}/Bi₂Te_{3-y}Se_{y} heterostructure as function of temperature for different values of δ, according to an embodiment of the present disclosure.

FIG. 21 illustrates a graphical representation of Temperature dependent (a) Hall mobility and (b) carrier concentration for optimum performance compositions of n-type Te/Bi₂Te_{3-y}Se_{y} heterostructures, according to an embodiment of the present disclosure.

FIGS. 22(a) and (b) illustrates a graphical representation of measured Hall resistance and longitudinal resistance of Te_{δ}/Bi₂Te_{3-y}Se_{y} heterostructure as a function of applied magnetic field at room temperature, according to an embodiment of the present disclosure.

### DETAILED DESCRIPTION OF THE INVENTION

In the following description, for purposes of explanation, numerous specific details are set forth in order to provide a thorough understanding of the present disclosure. It will be apparent, however, to one skilled in the art that the present disclosure can be practiced without these specific details.

Reference in this specification to “one embodiment” or “an embodiment” means that a particular feature, structure, or characteristic described in connection with the embodiment is included in at least one embodiment of the present disclosure. The appearance of the phrase “in an embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not for other embodiments.

Moreover, although the following description contains many specifics for the purposes of illustration, anyone skilled in the art will appreciate that many variations and/or alterations to said details are within the scope of the present disclosure. Similarly, although many of the features of the present disclosure are described in terms of each other, or in conjunction with each other, one skilled in the art will appreciate that many of these features can be provided independently of other features. Accordingly, this description of the present disclosure is set forth without any loss of generality to, and without imposing limitations upon, the present disclosure.

The present disclosure relates to heterostructure thermoelectric nanomaterials and a method for obtaining networked heterostructure nanomaterial having metal-semiconductor heterostructures. The present method is also applicable for semiconductor-semiconductor, metal-insulator as well as semiconductor-insulator heterostructures. Such heterostructures, having network of quantum well layers at nano-scale analogues to a honeycomb structure and filled with barrier layers materials, finds usages requiring quantum confinement and electrical transport. The present method for preparation of the thermoelectric heterostructure material is easily scalable. The application areas of such novel morphologies are electronic devices in general and thermoelectric devices in particular.

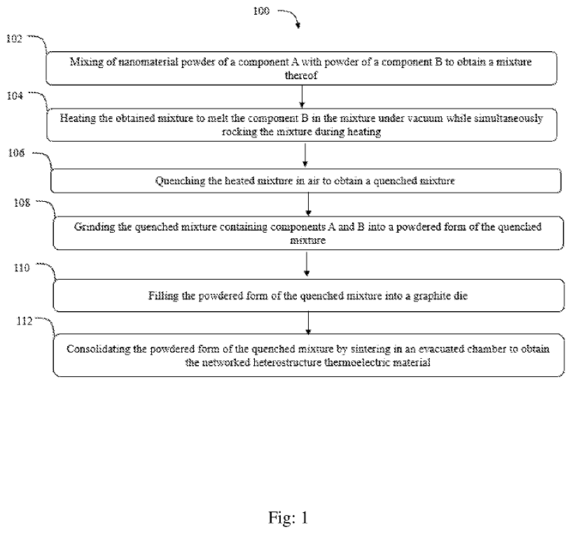

FIG. 1 illustrates a flow chart of a method 100 for obtaining networked heterostructure nanomaterial from component A and component B.

At step 102, powder of a nanomaterial component A is mixed with powder of a component B. The component A and the component B may be selected from a group comprising of: metal, semiconductor, and insulator. In an embodiment, component A can be metal, semiconductor or insulator and component B can be metal or semiconductor. Furthermore, the component A may be selected from highly doped semiconducting thermoelectric nanomaterials. In an embodiment, the component A is selected from a p-type highly doped semiconducting nanomaterial or a n-type highly doped semiconducting nanomaterial having carrier concentration in the range of 10¹⁹ per cm³ to 10²¹ per cm³. In the aforementioned embodiment, the selection of the components A and B are done in a manner such that melting point of the component A is greater than melting point of the component B. Furthermore, the components A and B may be so selected that the component B has lower chemical potential with respect to corresponding component A. In an embodiment, after the components A and B have been selected, the selected components A and B may be mixed in a ratio which may vary from 95:05 to 75:25 to obtain a mixture thereof.

With regard to step 102 above, in an example, the component B is selected form a group comprising of: tellurium, bismuth, Zinc, and the component A is selected as Bi₂Te₃₋ₓSeₓ, where x is in the range of 0.1 to 1.

In another example embodiment, the component B is selected form a group comprising of: tellurium, bismuth, Zinc, and the component A is selected as Sb₂₋ₓBiₓTe₃, where x is in the range of 0.1 to 1.

In another example embodiment, the component B is selected form a group comprising of: Bi₂Te₃, Sb₂Te₃, and the component A is selected form a group comprising of: Bi₂Se₃, Bi₂S₃, Sb₂Se₃, and Sb₂S₃.

At step 104, the mixture that is obtained by mixing the components A and B as mentioned above is heated under evacuation at the melting point of the component B. Simultaneously the mixture is rocked during the heating. In an example, the mixture is heated at such a temperature so that component A remains solid and only component B is melted. The rocking of component A and liquified component B is carried out for a period of 1-5 hours in a quartz ampoule. Thus, rocking of one solid and one liquid ingredient occurs in step 104.

At step 106, the heated mixture is quenched in air to obtain a quenched mixture. In an example, the quenched mixture is collected by breaking the quartz ampoule.

At step 108, the quenched mixture of components A and B is grinded to obtain a powdered form of the quenched mixture. In an example, the quenched mixture is powdered by using a conventional grinding technique.

At step 110, the powdered form of the quenched mixture is filled into a predesigned die. In an embodiment, the graphite die has internal diameter in the range of 10-40 mm.

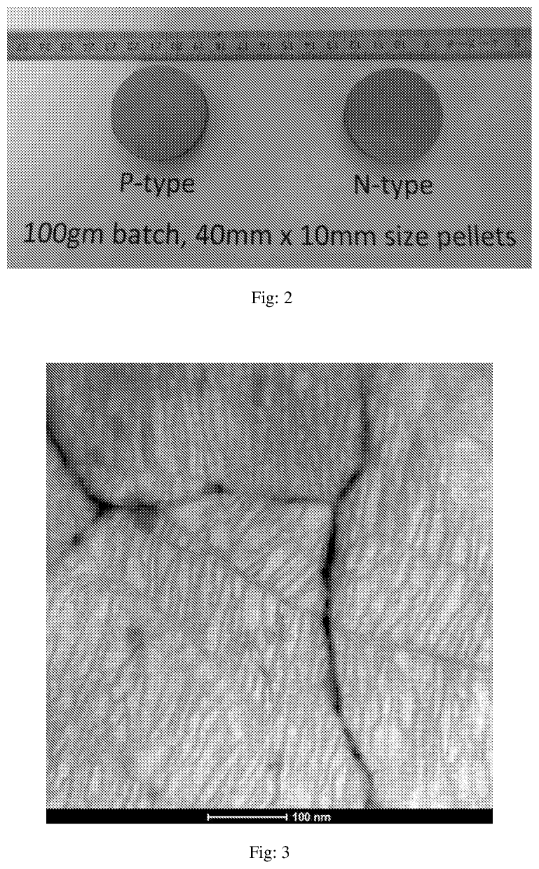

At step 112, the powdered form of the quenched mixture is consolidated in the die by sintering the mixture in an evacuated chamber to obtain the networked heterostructure nanomaterial. In an example, the die is made of graphite or Tungsten carbide. In an example, the die is made of some other suitable die material which may be selected as per requirement of pressure and temperature of consolidation. In an embodiment, the powdered form of the quenched mixture is consolidated in a Spark Plasma Sintering (SPS) machine. In an example, consolidation may be done in conventional Direct Current Hot Pres or Indirect Heating Hot Press. In an example, consolidation is carried out at pressure in the range of 20-100 MPa and temperature around the melting point of component B. In an embodiment, during the sintering process, excess amount of component B, if any, is thrown out of the graphite die and pellets with high density can be obtained. Photographs of consolidated pellets are shown in FIG. 2.

In step 112, controlled consolidation is done, such that liquefied component B during rocking step 104 spreads around component A nanomaterial grains and forms honeycomb like networked morphology at nano-scale upon solidification.

The present invention also discloses heterostructure thermoelectric nanomaterials. In an embodiment, the networked heterostructure thermoelectric nanomaterial can be both p-type and n-type metal-semiconductor bulk heterostructures of formula BiₓSb₂₋ₓD_{y}M_{3-y}/D_{δ}, where BiₓSb₂₋ₓD_{y}M_{3-y} is component A and D is component B. Elements D and M are selected from group of Te, Se, S and value of x, y, and δ is in the range of 0 to 3. In an embodiment, value of x, y, and δ is in the range of 0.1 to 1.

In an embodiment, the component A may be selected from highly doped semiconducting thermoelectric nanomaterials. In an embodiment, the component A is selected from a p-type highly doped semiconducting nanomaterial or a n-type highly doped semiconducting nanomaterial having carrier concentration in the range of 10¹⁹ per cm³ to 10²¹ per cm³.

In an embodiment, nanostructure of the heterostructure thermoelectric nanomaterial forms networked heterostructure morphology at nanoscale of range 1-10 nm. The component B has honeycomb like networked structure with voids therebetween and the voids are filled with component A.

In an embodiment, size of grains of the component A in the heterostructure thermoelectric nanomaterial are in the range of 5-10 nm at nano-scale. In an embodiment, size of the component B layers in the heterostructure thermoelectric material are in the range of 1-5 nm at nano-scale.

In an embodiment, a p-type networked heterostructure thermoelectric nanomaterial with enhanced efficiency can be obtained by using tellurium, zinc or bismuth as component B quantum well layer and Sb₂₋ₓBiₓTe₃ as component A barrier layer.

In an embodiment, a n-type networked heterostructure thermoelectric nanomaterial with enhanced efficiency can be obtained by using tellurium, zinc or bismuth as component B quantum well layer and Bi₂Te₃₋ₓSeₓ as component A barrier layer.

In an embodiment, for p-type tellurium/Sb₂₋ₓBiₓTe₃ heterostructure, a maximum value of Seebeck Coefficient obtained is 343.8μ V/K around room temperature. A maximum value of Electrical Conductivity obtained is 6.5×10⁴ S/m around room temperature for p-type tellurium/Sb₂₋ₓBiₓTe₃ heterostructure. A maximum value of Power Factor obtained is 7.6 mW/mK² around room temperature for p-type tellurium/Sb₂₋ₓBiₓTe₃ heterostructure. A minimum value of Thermal Conductivity obtained is 1.06 W/m·K around room temperature for p-type tellurium/Sb₂₋ₓBiₓTe₃ heterostructure. A maximum value of Figure of Merit (ZT) obtained is 2.1 around room temperature for p-type tellurium/Sb₂₋ₓBiₓTe₃ heterostructure. An average value of Figure of Merit (ZT) obtained is 1.3 in room temperature to 250° C. temperature range for p-type tellurium/Sb₂₋ₓBiₓTe₃ heterostructure. Further, quantum confinement is confirmed by quantized plateaus in Hall resistance and correlated reducing longitudinal resistance peaks as a function of applied magnetic field at room temperature for p-type tellurium/Sb₂₋ₓBiₓTe₃ heterostructure.

In an embodiment, for n-type tellurium/Bi₂Te₃₋ₓSeₓ heterostructure, maximum value of Seebeck Coefficient obtained is (negative) 199.8μ V/K around room temperature. A maximum value of Electrical Conductivity obtained is 1.5×10⁵ S/m around room temperature for n-type tellurium/Bi₂Te₃₋ₓSeₓ heterostructure. A maximum value of Power Factor obtained is 6.1 mW/mK² around room temperature for n-type tellurium/Bi₂Te₃₋ₓSeₓ heterostructure. A minimum value of Thermal Conductivity obtained is 0.71 W/m·K around room temperature for n-type tellurium/Bi₂Te₃₋ₓSeₓ heterostructure. A maximum value of Figure of Merit (ZT) obtained is 2.6 around room temperature for n-type tellurium/Bi₂Te₃₋ₓSeₓ heterostructure. An average value of Figure of Merit (ZT) obtained is 2.0 in room temperature to 250° C. temperature range for n-type tellurium/Bi₂Te₃₋ₓSeₓ heterostructure. Further, quantum confinement is confirmed by quantized plateaus in Hall resistances and correlated reducing longitudinal resistance peaks as a function of applied magnetic field at room temperature for n-type tellurium/Bi₂Te₃₋ₓSeₓ heterostructure.

In an embodiment, the heterostructures of the thermoelectric material obtained by the method 110 demonstrate enhanced Seebeck coefficient, increased electrical conductivity, reduced thermal conductivity and consequently, enhanced figure of merit. The sign of Seebeck Coefficient of heterostructure of the thermoelectric material can be determined by the sign of Seebeck coefficient of the component A. Enhancement in Seebeck coefficient and/or electrical conductivity is obtained and therefore, exceptional enhancement in power factor is obtained due to quantum confinement effect. Further, both n-type and p-type thermoelectric heterostructure materials can be realized by the method 100.

In an embodiment, enhanced figure of merit for both p-type and n-type thermoelectric heterostructure materials are demonstrated in the same material system by just change of polarity of semiconducting barrier layer. The method 100 provides a pair of materials for practical efficient thermoelectric devices and discloses the knowledge of carrier injection from barrier layer to quantum well layer for thermoelectric transport properties.

In an embodiment, quantum confinement in the heterostructures produced by the method 100 is demonstrated by quantum well layers in few nm ranges in transmission electron microscopy. Further, enhanced values of power factor are shown in thermoelectric measurements and observation of Quantum Hall Effect. Quantum confinement is occurred in metallic or semiconducting layers of component B. Further, band offset is occurred for quantum confinement obtained by semiconducting thermoelectric nanomaterial barrier layers of component A. Accordingly, reduction in thermal conductivity is obtained due to band offset values higher than typical phonon energies. Furthermore, carrier injection is occurred from barrier layer of component A into quantum well layer of component B to obtain different polarity thermoelectric heterostructures in the present method.

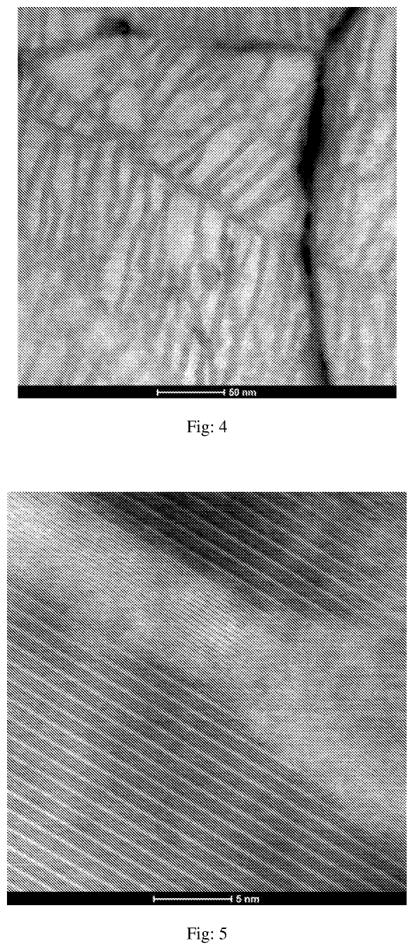

High Resolution-Transmission Electron Microscopy (HR-TEM) of lamella taken from the consolidated pellet demonstrate the unique morphology heterostructure at nano-scale. HR-TEM image at 100 nm scale in FIG. 3 shows honeycomb like structure of component B, wherein voids of the structure are filled by component A. The structural detail becomes more apparent in HR-TEM image at 50 nm scale shown in the FIG. 4.

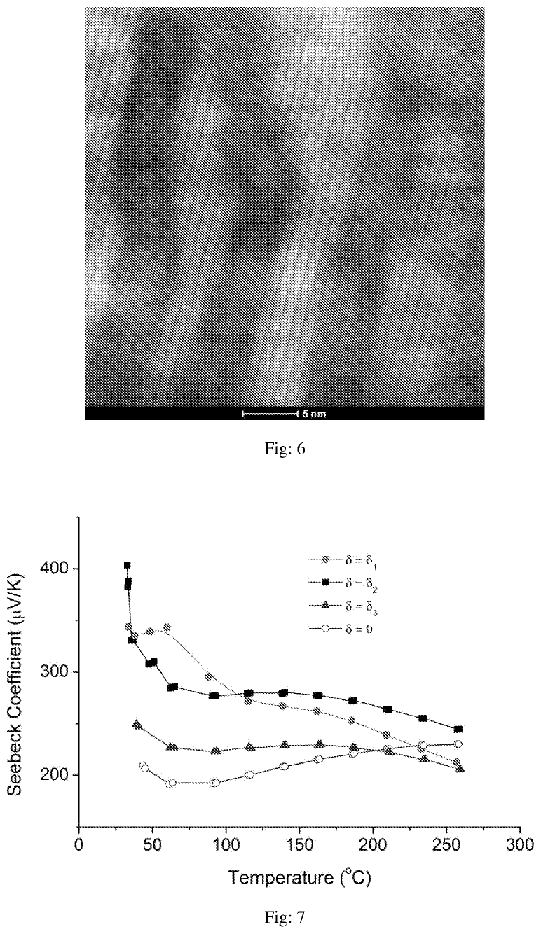

Atomic level details of the heterostructure are demonstrated in HR-TEM images at 5 nm scale shown in FIGS. 5 and 6. Identical atomic layers of component B and quintuple layers, comprising of a group of different atoms repeating in the crystal lattice, of component A are demonstrated in these figures. The size specifications of few nm of layers demonstrate the formation of 2D heterostructure. Resultantly, networked heterostructure formation method of the present disclosure is demonstrated.

The consolidated pellet of the heterostructure is cut into appropriate shapes and dimensions for thermoelectric measurements, while maintaining the directionality. Electrical conductivity and Seebeck coefficient are measured simultaneously. The system accuracy is checked using bismuth telluride of NIST SRM 3451 standard. Thermal diffusivity is measured using a standard Laser Flash Apparatus as per ASTM 1461 standard. Specific heat is measured using a Differential Scanning calorimeter with sapphire NIST SRM 720 standards. Room temperature density is determined using an Archimedes' apparatus using standard density of 99.9% ethanol. Thermal conductivity is calculated by multiplying the measured values of thermal diffusivity, specific heat and density. Power factor and figure of merit values are calculated from the aforesaid measurement data.

The measured values of Seebeck coefficient on heterostructure sample is much higher than corresponding values for component A and B. Further, the temperature dependence of Seebeck coefficient also does not correspond to component A and B. Thus, entirely unique functional property is obtained. This confirms formation of the heterostructure of component A and B, rather than just composite formation.

The measured values of electrical conductivity on heterostructure sample is much higher than corresponding values for component A and it approaches the corresponding high value of B. Electrical conductivity values in semi-metallic range is demonstrated for idealistic semiconducting Seebeck coefficient value sample.

The measured values of Seebeck coefficient and electrical conductivity shows that the conventional interrelation, popularly known as Pisrenko relation, between Seebeck coefficient and electrical conductivity is broken. Seebeck coefficient and electrical conductivity are enhanced in the heterostructure. This enhanced the calculated values of Power Factor (S²δ), which is a clear evidence of quantum confinement in the heterostructure produced by the method of the present invention.

The measured values of thermal diffusivity may show some increase, but it can be controlled by proper choice of the contents of components A and B. Specific heat is a bulk property and averaging effect of the corresponding values of components A and B may help in some control of its value. The values of resultantly calculated thermal conductivity are retained to corresponding values of the component B and it is much lower than corresponding value for component A in their bulk forms.

The sign change of the Seebeck coefficient (p-type or n-type) of the heterostructure of components A and B is demonstrated with change in carrier type in the component A. This demonstrates charge injection mechanism to realize both n-type and p-type thermoelectric heterostructures in same material system.

Enhancement of power factor, control of thermal conductivity values and change in type by choice of carrier type in component A have resulted in demonstration of enhanced figure of merit values >2 for both n-type and p-type heterostructures. Thus, both p-type and n-type enhanced efficiency thermoelectric heterostructures in same class of material systems with almost identical temperature dependence of thermoelectric properties are demonstrated.

Thermoelectric efficiency enhancement knowledge in heterostructures is demonstrated in the present invention using networked heterostructures. This knowledge is valid for all kind of heterostructures, including superlattices, quantum wells, quantum wires, quantum dots and combinations thereof.

Thermoelectric efficiency enhancement knowledge in heterostructures is demonstrated in the present invention using component A as semiconducting materials and component B as metal. This knowledge is valid for semiconducting, metallic and insulator components A and B as well as combinations thereof.

Thermoelectric efficiency enhancement knowledge in heterostructures is demonstrated in the present invention using size parameters and band offset values of components A and B. This knowledge is valid for optimized values of quantum well and barrier size specification and optimized values of band offsets by suitable selection of components A and B as well as combinations thereof.

### EXAMPLES

The following examples are given by way of illustration of the present disclosure and should not be construed to limit the scope of present disclosure. It is to be understood that both the foregoing general description and the following detailed description are exemplary and explanatory only and are intended to provide further explanation of the subject matter. The present disclosure is demonstrated using semiconductor of Formula I: BiₓSb₂₋ₓD_{y}M_{3-y} as component A and metal D as component B for the heterostructure BiₓSb₂₋ₓD_{y}M_{3-y}/Do. In formula I, elements D and M can be chosen from among the chalcogenides Te, Se and S.

### Example 1: Te_{δ}/BiₓSb₂₋ₓTe₃ Heterostructure

Highly doped p-type semiconducting BiₓSb₂₋ₓTe₃ nanomaterial is taken as component A and Te powder is taken as component B. Other choices for component B for this component A material can be Bi, Zn, Sn, In and other such metals and semiconductors having meting point lower than that of BiₓSb₂₋ₓTe₃.

The nanomaterial powder of BiₓSb₂₋ₓTe₃ and powder of Te are mixed together and filled in a quartz ampoule. The values of both x and δ are taken in the range 0.25-1. The ampoule is evacuated and purged with inert gas and thereafter, sealed under evacuation condition using conventional LPG-Oxygen combination flame. This sealed ampoule is placed in rocking tube furnace and heated at around 400° C. to melt the Te without affecting BiₓSb₂₋ₓTe₃. This mixer of melted Te and BiₓSb₂₋ₓTe₃ is rocked for 1-5 hours and quenched in air. The resulting specimen is collected by breaking the ampoule and powdered by conventional grinding method.

The powdered specimen from the previous process is filled in a graphite die. Graphite dies of internal diameter between 10-40 mm are taken and this can be any value depending upon requirement of the sample size. Tungsten carbide and other suitable die materials can be taken as per requirement of pressure and temperature of consolidation process.

The powdered specimen inside graphite is consolidated in Spark Plasma Sintering (SPS) machine. This consolidation is carried out at pressure range between 25-100 MPa, temperature around the melting points of Te, i.e., 400° C., and time between 2-15 minutes. In place of SPS, other similar machines such as Direct Current Hot Press (DCHP), Indirect Heating Hot Press etc. can also be used for consolidation. Excess amount of Te is thrown out of the graphite die depending upon the values of 8 in this consolidation process.

Solid specimens of thickness in 2-15 mm range are produced as per requirement in consolidation process. Any thickness may be taken as per requirement and availability of resources. The solid specimen is cut into different sizes and shapes for various thermoelectric measurements and Hall measurements, while maintaining directionality. A lamella was also taken from the solid specimen for HR-TEM imaging.

HR-TEM imaging is shown in FIGS. 3-6. These figures demonstrate formation of Te_{δ}/Bi_{0.5}Sb_{1.5}Te₃ heterostructure in honeycomb like networked morphology of Te and void of network filled-in by BiₓSb₂₋ₓTe₃ nanomaterials. Te can be identified by same type of atomic layers in FIG. 5 and FIG. 6 and BiₓSb₂₋ₓTe₃ can also be identified in these figures by quintuple layers of multiple types of atoms. This provides formation of Te_{δ}/BiₓSb₂₋ₓTe₃ networked heterostructure with the method of the present invention.

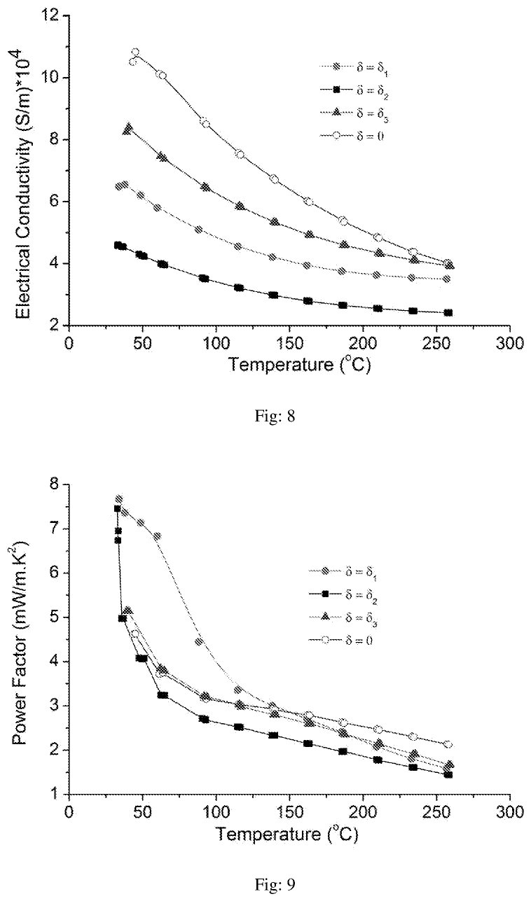

Seebeck coefficient and electrical conductivity are measured simultaneously by using 8-10 mm (Length)×3-4 mm (width)×1-2 mm (thickness) sample of Te_{δ}/BiₓSb₂₋ₓTe₃ heterostructure in room temperature to 250° C. temperature range. These measurements for typical values of 8 are plotted in FIG. 7 and FIG. 8 respectively. Seebeck coefficient is enhanced in the heterostructure in comparison to bare BiₓSb₂₋ₓTe₃ (δ=0). Electrical conductivity is reduced at low temperatures in comparison to bare BiₓSb₂₋ₓTe₃ (δ=0). Enhancement in Seebeck coefficient is more prominent than reduction in electrical conductivity. This resulted in enhancement in power factor, which is plotted in FIG. 9. The peak value of power factor Obtained is 7.5 mW/mK². Such a high value of power factor confirms quantum confinement effect in Te_{δ}/BiₓSb₂₋ₓTe₃ heterostructure.

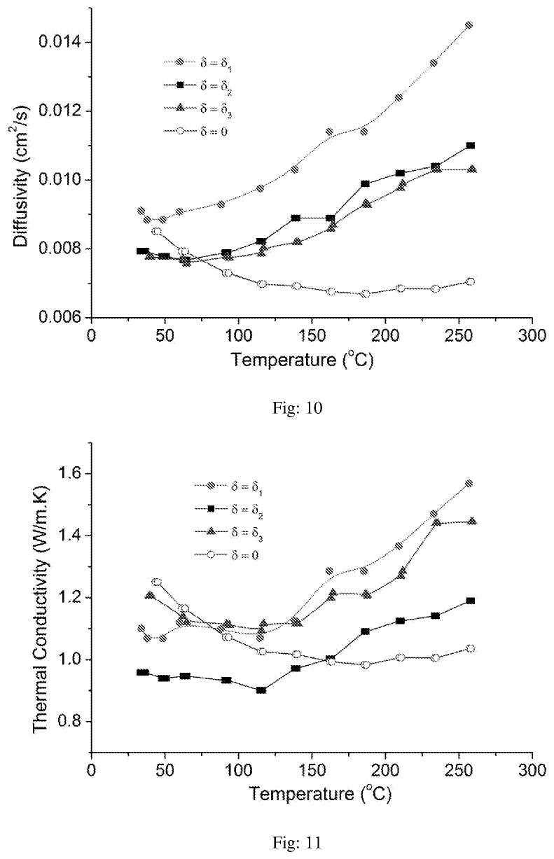

Thermal diffusivity is measured using 12.7 mm (diameter)×1-2 mm thickness sample of Te_{δ}/BiₓSb₂₋ₓTe₃ heterostructure in room temperature to 250° C. temperature range using laser flash apparatus, which are plotted in FIG. 10. Specific heat is measured in room temperature to 250° C. temperature range by using Differential Scanning calorimeter apparatus. Density is measured at room temperature and it is assumed relatively constant in room temperature to 250° C. temperature range for the purpose of calculating thermal conductivity. The calculated values of thermal conductivity by multiplying the measured values of thermal diffusivity, specific heat and density are plotted in FIG. 11.

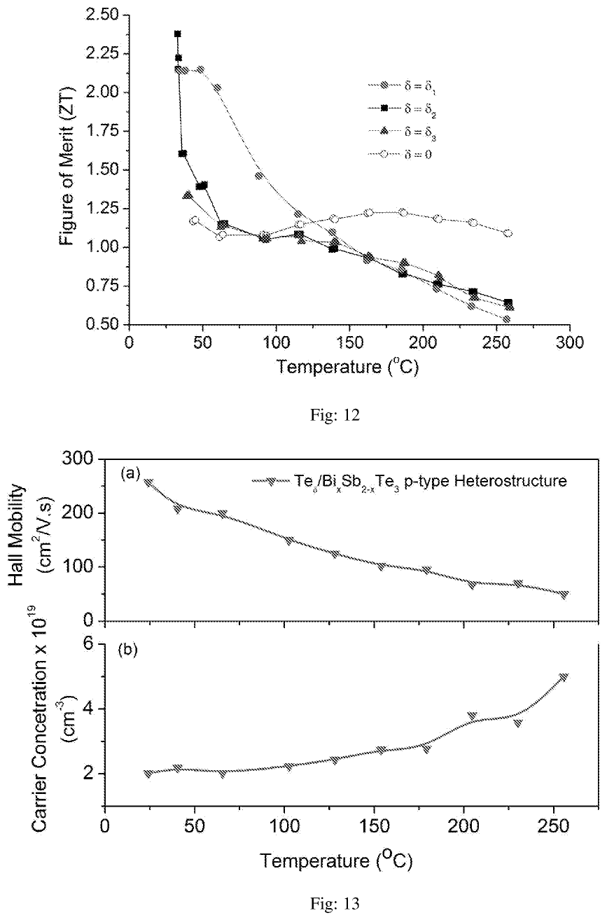

Figure of merit is calculated using the values of power factor and thermal conductivity at respective temperatures, which are plotted in FIG. 12. This demonstrates enhanced figure of merit value of 2.3 in Te_{δ}/BiₓSb₂₋ₓTe₃ heterostructure. Highest value of average figure of merit value obtained for this heterostructure is 1.3, for which peak value is 2.15. The values of thermoelectric parameters for this highest average figure of merit composition in Te_{δ}/BiₓSb₂₋ₓTe₃ heterostructure are tabulated in table 1.

TABLE 1

| | | Electrical | Seebeck | | Power | Thermal | Specific | | Thermal | Figure |
|---|---|---|---|---|---|---|---|---|---|---|
| Temp | Temp | Resistivity | Coefficient | Conductivity | Factor | Diffusivity | Heat | Density | Conductivity | of |
| (° C.) | (K) | (μΩ · m) | (μV/K) | (S/m*10⁴) | (mW/mK²) | (cm²/s) | (J/g · K) | (g/cm³) | (W/m · K) | Merit |
| 33 | 306 | 15.4079 | 343.8271 | 6.49018 | 7.6725 | 0.00911 | 0.1808 | 6.6851 | 1.10112 | 2.13863 |
| 37 | 310 | 15.2669 | 335.2391 | 6.55012 | 7.36137 | 0.00884 | 0.1808 | 6.6851 | 1.06848 | 2.14144 |
| 48 | 321 | 16.1085 | 339.0505 | 6.2079 | 7.13631 | 0.00884 | 0.1808 | 6.6851 | 1.06848 | 2.14753 |
| 59 | 332 | 17.2219 | 343.0634 | 5.80656 | 6.83389 | 0.00908 | 0.18446 | 6.6851 | 1.11972 | 2.03174 |
| 88 | 361 | 19.6436 | 295.5296 | 5.09072 | 4.44612 | 0.00929 | 0.17691 | 6.6851 | 1.09867 | 1.46132 |
| 114 | 387 | 21.9891 | 271.5246 | 4.54771 | 3.35283 | 0.00976 | 0.16399 | 6.6851 | 1.06995 | 1.21525 |
| 138 | 411 | 23.7492 | 267.0072 | 4.21067 | 3.00191 | 0.0103 | 0.16343 | 6.6851 | 1.12533 | 1.09701 |
| 161 | 434 | 25.4133 | 262.3209 | 3.93495 | 2.70773 | 0.0114 | 0.16873 | 6.6851 | 1.28589 | 0.91561 |
| 185 | 458 | 26.6454 | 253.1705 | 3.75299 | 2.40549 | 0.0114 | 0.16873 | 6.6851 | 1.28589 | 0.85751 |
| 209 | 482 | 27.5514 | 239.0662 | 3.62958 | 2.0744 | 0.0124 | 0.16493 | 6.6851 | 1.36722 | 0.7314 |
| 232 | 505 | 28.2288 | 225.5487 | 3.54248 | 1.80214 | 0.0134 | 0.16416 | 6.6851 | 1.47058 | 0.61999 |
| 256 | 529 | 28.5465 | 212.7638 | 3.50306 | 1.58578 | 0.0145 | 0.16186 | 6.6851 | 1.56899 | 0.53549 |

| | |
|---|---|
| Average Figure of Merit ZT in room temperature to 250° C. temperature range | 1.3 |

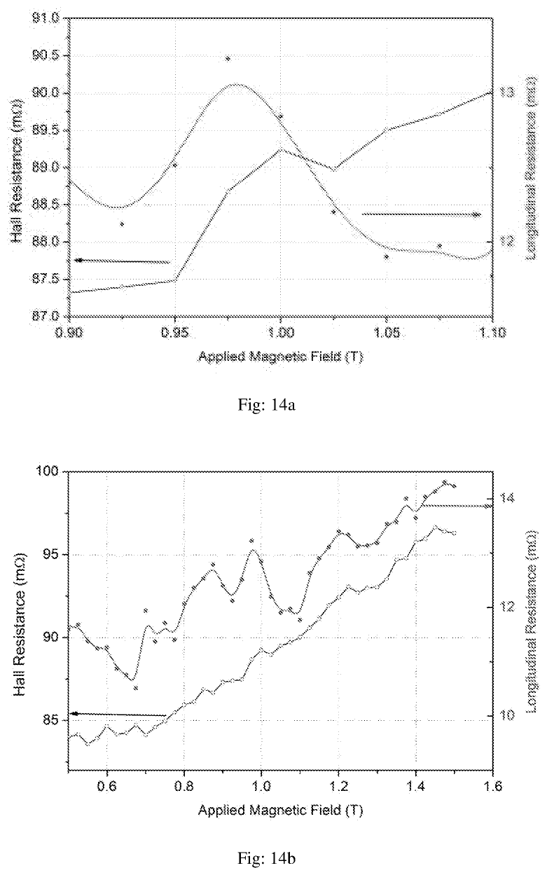

Electrical transport properties in magnetic field have been studied using 8-10 mm×8-10 mm×0.7-0.9 mm size samples in four-probe Van der pauw configuration. Measurements have been made at 9 kG magnetic field using 5 mA constant current in room temperature to 250° C. temperature range. Resistivity and Hall voltage measurements have been performed, while averaging over geometry and current reversal for realistic estimation of transport properties in these bulk samples. The oven containing the sample is evacuated and purged with helium for stable measurement conditions. The calculated values of Hall mobility and carrier concentration are plotted in FIG. 13 for p-type Te_{δ}/BiₓSb₂₋ₓTe₃ heterostructure.

The p-type Te_{δ}/BiₓSb₂₋ₓTe₃ heterostructure shows enhanced room temperature mobility, which decreases at elevated temperatures. At the same time, carrier concentration increases with increase in temperature and it is in the optimum range of 10¹⁹ cm⁻³ for bulk thermoelectric materials.

Magneto-transport measurements are done on 8-10 mm (Length)×8-10 mm (width)×0.5-0.9 mm (thickness) sample of Te_{δ}/BiₓSb₂₋ₓTe₃ heterostructure using Hall measurement system. The Hall resistance (R_{xy}) showed Landau level plateaus and longitudinal resistance measurement (Rₓₓ) showed dips at the commencement of Landau plateaus as a function of applied magnetic field. R_{xy} and Rₓₓ are plotted as a function of applied magnetic field at room temperature in FIG. 14. It is shown that quantized Hall plateaus are correlated with reducing longitudinal resistance. This correlation is more apparent in FIG. 14(a) for single peak and confirms presence of 2D transport contribution. This correlation in position of Landau plateaus in R_{xy} and dips in Rₓₓ showed observation of Quantum Hall effect in Te_{δ}/BiₓSb₂₋ₓTe₃ heterostructure and thereby, establishes role of quantum size effects in thermoelectric efficiency enhancement in Te_{δ}/BiₓSb₂₋ₓTe₃ heterostructure produced in the present invention.

### Example 2: Te_{δ}/Bi₂Te_{3-y}Se_{y} Heterostructure

Highly doped n-type semiconducting Bi₂Te_{3-y}Se_{y} nanomaterial is taken as component A and Te powder is taken as component B. Other choices for component B for this component A material can be Bi, Zn, Sn, In and other such metals and semiconductors having meting point lower than that of Bi₂Te_{3-y}Se_{y}.

The nanomaterial powder of Bi₂Te_{3-y}Se_{y} and powder of Te are mixed together and filled in a quartz ampoule. The values of both y and δ are taken in the range 0.25-1. The ampoule is evacuated and purged with inert gas and thereafter, sealed under evacuation condition using conventional LPG-Oxygen combination flame. This sealed ampoule is placed in rocking tube furnace and heated at around 400° C. to melt the Te without affecting Bi₂Te_{3-y}Se_{y}. This mixer of melted Te and Bi₂Te_{3-y}Se_{y} is rocked for 1-5 hours and quenched in air. The resulting specimen is collected by breaking the ampoule and powdered by conventional grinding method.

The powdered specimen from the previous process is filled in a graphite die. Graphite dies of internal diameter between 10-40 mm are taken and this can be any value depending upon requirement of the sample size. Tungsten carbide and other suitable die materials can be taken as per requirement of pressure and temperature of consolidation process.

The powdered specimen inside graphite is consolidated in Spark Plasma Sintering (SPS) machine. This consolidation is carried out at pressure range between 25-100 MPa, temperature around the melting points of Te, i.e., 400° C., and time between 2-15 minutes. In place of SPS, other similar machines such as Direct Current Hot Press (DCHP), Indirect Heating Hot Press etc. can also be used for consolidation. Excess amount of Te is thrown out of the graphite die depending upon the values of 8 in this consolidation process.

Solid specimens of thickness in 2-15 mm range are produced as per requirement in consolidation process. Any thickness may be taken as per requirement and availability of resources. The solid specimen is cut into different sizes and shapes for various thermoelectric measurements and Hall measurements, while maintaining directionality.

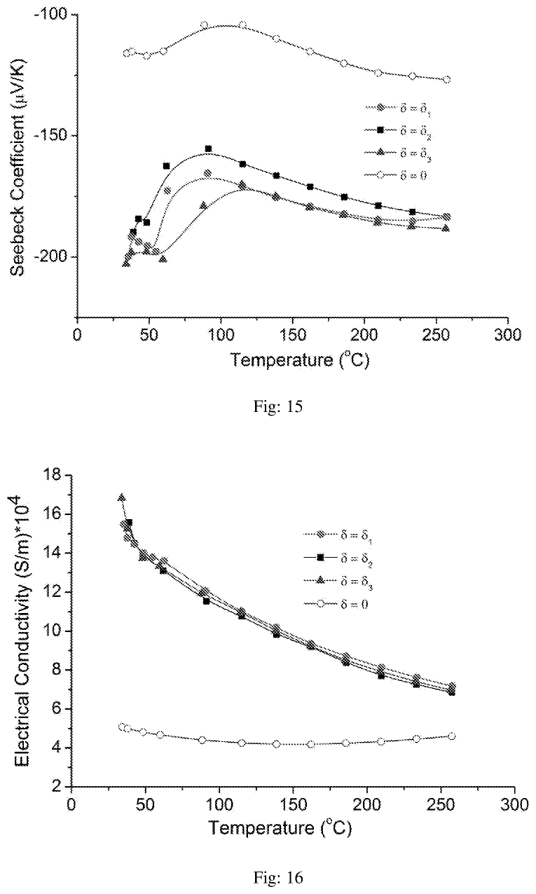

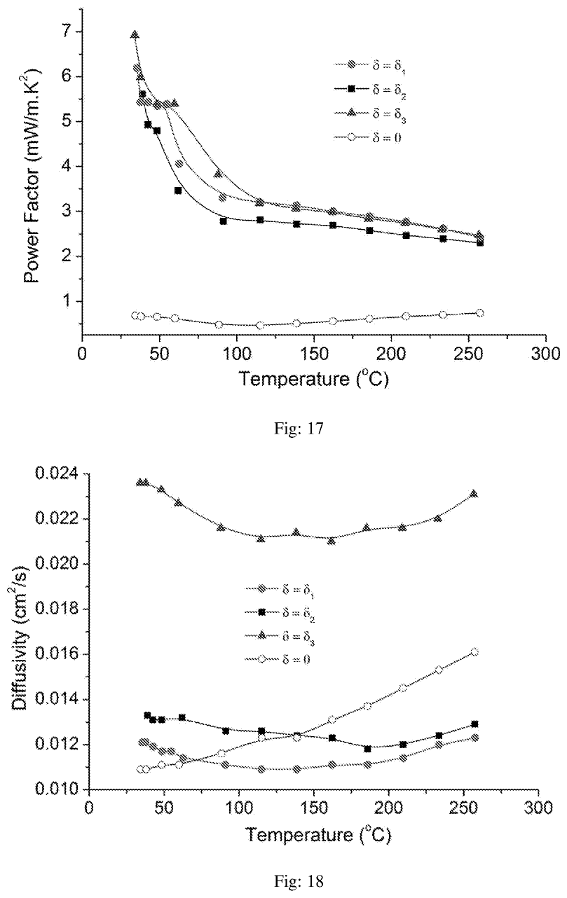

Seebeck coefficient and electrical conductivity are measured simultaneously by using 8-10 mm (Length)×3-4 mm (width)×1-2 mm (thickness) sample of Te_{δ}/Bi₂Te_{3-y}Se_{y} heterostructure in room temperature to 250° C. temperature range. These measurements for typical values of 8 are plotted in FIGS. 15 and 16 respectively. Seebeck coefficient is enhanced in the heterostructure in comparison to bare Bi₂Te_{3-y}Se_{y} (δ=0). Electrical conductivity is also enhanced in comparison to bare Bi₂Te_{3-y}Se_{y} (δ=0). Enhancement in Seebeck coefficient as well as electrical conductivity resulted in enhancement in power factor, which is plotted in FIG. 17. The peak value of power factor Obtained is 7.0 mW/mK². Such a high value of power factor confirms quantum confinement effect in the Te_{δ}/Bi₂Te_{3-y}Se_{y} heterostructure.

Thermal diffusivity is measured using 12.7 mm (diameter)×1-2 mm thickness sample of Te_{δ}/Bi₂Te_{3-y}Se_{y} heterostructure in room temperature to 250° C. temperature range using laser flash apparatus, which are plotted in FIG. 18. Specific heat is measured in room temperature to 250° C. temperature range by using Differential Scanning calorimeter apparatus. Density is measured at room temperature and it is assumed relatively constant in room temperature to 250° C. temperature range for the purpose of calculating thermal conductivity. The calculated values of thermal conductivity by multiplying the measured values of thermal diffusivity, specific heat and density are plotted in FIG. 19.

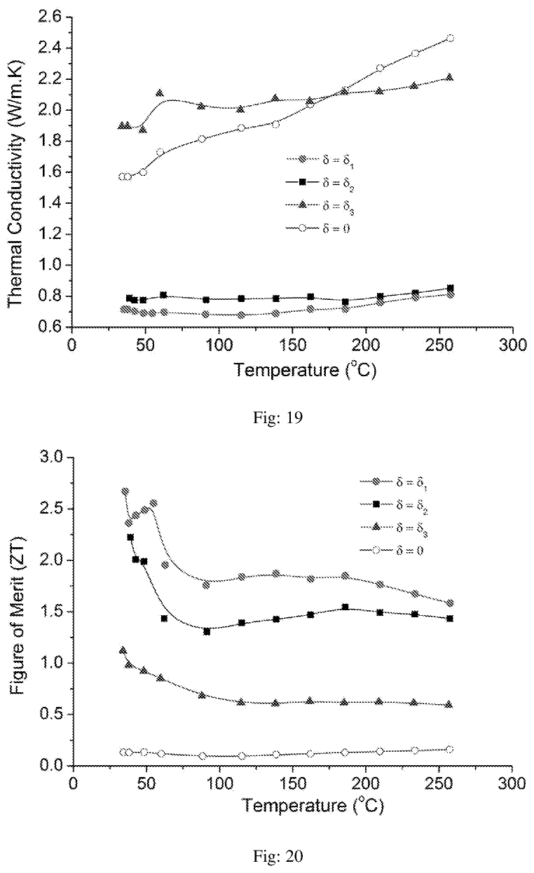

Figure of merit is calculated using the values of power factor and thermal conductivity at respective temperatures, which are plotted in FIG. 20. This demonstrates enhanced figure of merit value of 2.6 in Te_{δ}/Bi₂Te_{3-y}Se_{y} heterostructure. Highest value of average figure of merit value obtained for this heterostructure is 2.0. The values of thermoelectric parameters for this highest average figure of merit composition in Te_{δ}/Bi₂Te_{3-y}Se_{y} heterostructure are tabulated in table 2.

TABLE 2

| | | Electrical | Seebeck | | Power | Thermal | Specific | | Thermal | Figure |
|---|---|---|---|---|---|---|---|---|---|---|
| Temp | Temp | Resistivity | Coefficient | Conductivity | Factor | Diffusivity | Heat | Density | Conductivity | of |
| (° C.) | (K) | (μΩ · m) | (μV/K) | (S/m*10⁴) | (mW/mK²) | (cm²/s) | (J/g · K) | (g/cm³) | (W/m · K) | Merit |
| 35 | 308 | 6.4564 | −199.8834 | 15.48851 | 6.18818 | 0.0121 | 0.07981 | 7.40221 | 0.71487 | 2.66947 |
| 37 | 310 | 6.7621 | −191.7034 | 14.78831 | 5.43473 | 0.0121 | 0.07981 | 7.40221 | 0.71487 | 2.36213 |
| 42 | 315 | 6.9112 | −193.7387 | 14.46927 | 5.43099 | 0.0119 | 0.07981 | 7.40221 | 0.70305 | 2.43863 |
| 48 | 321 | 7.1457 | −195.4344 | 13.99443 | 5.34512 | 0.0117 | 0.07981 | 7.40221 | 0.69124 | 2.48834 |
| 54 | 327 | 7.2557 | −197.7233 | 13.78227 | 5.38811 | 0.0117 | 0.07981 | 7.40221 | 0.69124 | 2.55505 |
| 62 | 335 | 7.3476 | −172.6592 | 13.60989 | 4.05727 | 0.0114 | 0.08258 | 7.40221 | 0.69689 | 1.95436 |
| 90 | 363 | 8.29 | −165.4421 | 12.06273 | 3.3017 | 0.0111 | 0.08316 | 7.40221 | 0.68325 | 1.75808 |
| 115 | 388 | 9.0973 | −170.8103 | 10.99227 | 3.20712 | 0.0109 | 0.08397 | 7.40221 | 0.67747 | 1.8372 |
| 138 | 411 | 9.8308 | −175.4617 | 10.17211 | 3.13167 | 0.0109 | 0.08537 | 7.40221 | 0.6888 | 1.87147 |
| 162 | 435 | 10.6977 | −179.0948 | 9.3478 | 2.9983 | 0.0111 | 0.08732 | 7.40221 | 0.71748 | 1.81861 |
| 185 | 458 | 11.4777 | −182.2056 | 8.71255 | 2.89247 | 0.0111 | 0.08732 | 7.40221 | 0.71748 | 1.85001 |
| 209 | 482 | 12.2987 | −184.8968 | 8.13094 | 2.7707 | 0.0114 | 0.08984 | 7.40221 | 0.75812 | 1.7639 |
| 233 | 506 | 13.1167 | −185.2583 | 7.62387 | 2.61656 | 0.012 | 0.0892 | 7.40221 | 0.79232 | 1.67277 |
| 257 | 530 | 13.9298 | −183.6065 | 7.17885 | 2.42009 | 0.0123 | 0.08908 | 7.40221 | 0.81102 | 1.58326 |

| | |
|---|---|
| Average Figure of Merit ZT in room temperature to 250° C. temperature range | 2.0 |

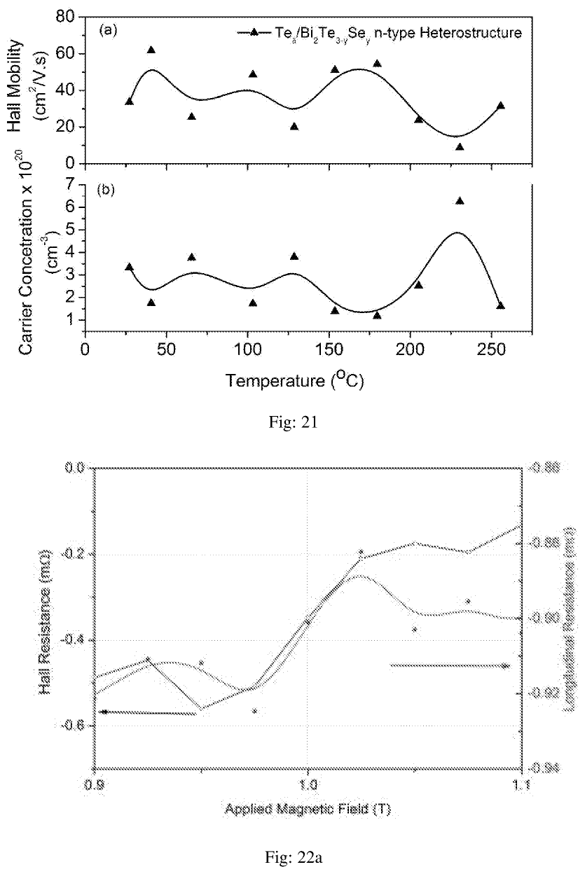

Electrical transport properties in magnetic field have been studied using 8-10 mm×8-10 mm×0.7-0.9 mm size samples in four-probe Van der pauw configuration. Measurements have been made at 9 kG magnetic field using 5 mA constant current in room temperature to 250° C. temperature range. Resistivity and Hall voltage measurements have been performed, while averaging over geometry and current reversal for realistic estimation of transport properties in these bulk samples. The oven containing the sample is evacuated and purged with helium for stable measurement conditions. The calculated values of Hall mobility and carrier concentration are plotted in FIG. 21 for n-type Te_{δ}/Bi₂Te_{3-y}Se_{y}.

In case of n-type Te_{δ}/Bi₂Te_{3-y}Se_{y} heterostructure, carrier concentration has been observed in the range of 10²⁰ cm⁻³, which is quite high value. Also, it does not show much temperature dependence. The Hall mobility in this material is very low compared to that reported for constituent materials of the heterostructure. Further, it does not show much temperature dependence. The reduced mobility in the n-type heterostructure may be associated with increase in carrier-carrier scattering at such a high carrier concentration.

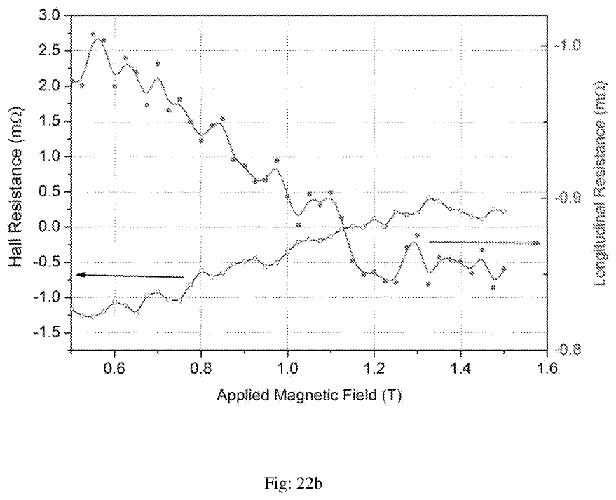

Magneto-transport measurements are done on 8-10 mm (Length)×8-10 mm (width)×0.5-0.9 mm (thickness) sample of Te_{δ}/Bi₂Te_{3-y}Se_{y} heterostructure using Hall measurement system. The Hall resistance (R_{xy}) showed Landau level plateaus and longitudinal resistance measurement (Rₓₓ) showed dips at the commencement of Landau plateaus as a function of applied magnetic field. R_{xy} and Rₓₓ are plotted as function of applied magnetic field at room temperature in FIG. 22. It is shown that quantized Hall plateaus are correlated with reducing longitudinal resistance. This correlation is more apparent in FIG. 22(a) for single peak and confirms presence of 2D transport contribution. This correlation in position of Landau plateaus in R_{xy} and dips in Rₓₓ showed observation of Quantum Hall effect in Te_{δ}/BiₓSb₂₋ₓTe₃ heterostructure and thereby, establishes role of quantum size effects in thermoelectric efficiency enhancement in Te_{δ}/Bi₂Te_{3-y}Se_{y} heterostructure produced in the present invention.

We claim:

1. A method (100) of obtaining networked heterostructure nanomaterial by synthesis, the method comprising:
a. mixing (102) nanomaterial powder of a component A with powder of a component B in a ratio selected from a range of 95:05 to 75:25 to obtain a mixture thereof;
b. heating (104) the obtained mixture to melt the component B in the mixture under vacuum while simultaneously rocking the mixture during heating;
c. quenching (106) the heated mixture in air to obtain a quenched mixture;
d. grinding (108) the quenched mixture containing components A and B into a powdered form of the quenched mixture;
e. filling (110) the powdered form of the quenched mixture into a predesigned die; and
f. consolidating (112) the powdered form of the quenched mixture by sintering in an evacuated chamber to obtain the networked heterostructure nanomaterial.

2. The method (100) as claimed in claim 1, wherein the method further comprises selecting the component A and the component B from a group comprising: metal, semiconductor, and insulator.

3. The method (100) as claimed in claim 1, wherein the method further comprises selecting the component A and the component B such that melting point of the component A is greater than melting point of the component B.

4. The method (100) as claimed in claim 1, wherein the method further comprises selecting the component B from group comprising of: tellurium, bismuth, Zinc and selecting the component A as Bi₂Te₃₋ₓSeₓ, wherein x in the range 0.1 to 1.

5. The method (100) as claimed in claim 1, wherein the method further comprises selecting the component B from group comprising of: tellurium, bismuth, Zinc and selecting the component A as Sb₂₋ₓBiₓTe₃, wherein x in the range 0.1 to 1.

6. The method (100) as claimed in claim 1, wherein the method further comprises selecting the component B from group comprising of: Bi₂Te₃ and Sb₂Te₃ and selecting the component A from a group comprising of: Bi₂Se₃, Bi₂S₃, Sb₂Se₃, and Sb₂S₃.

7. A heterostructure thermoelectric nanomaterial, having heterostructure of formula BiₓSb₂₋ₓD_{y}M_{3-y}/D_{δ}:
wherein BiₓSb₂₋ₓD_{y}M_{3-y} is component A and D is component B, wherein elements D and M are selected from group of Te, Se, S; wherein value of x, y, and δ is in the range of 0 to 3.

8. The heterostructure thermoelectric nanomaterial as claimed in claim 7, wherein value of x, y, and δ is in the range of 0.1 to 1.

9. The heterostructure thermoelectric nanomaterial as claimed in claim 7, wherein nanostructure of the heterostructure thermoelectric nanomaterial forms networked heterostructure morphology at nanoscale of range 1-10 nm, wherein component B has honeycomb like networked structure with voids therebetween and wherein the voids are filled with component A.

10. The heterostructure thermoelectric nanomaterial as claimed in claim 7, wherein the heterostructure thermoelectric nanomaterial comprises layers of the component B having size in the range of 1-5 nm.

11. The heterostructure thermoelectric nanomaterial as claimed in claim 7, wherein the heterostructure thermoelectric nanomaterial comprises grains of the component A having size in the range of 5-10 nm.

12. The heterostructure thermoelectric nanomaterial as claimed in claim 7, wherein the concept of enhancement in thermoelectric efficiency of the networked heterostructure comprising of:
a. quantum confinement in metallic or semiconducting layers of component B;
b. band offset for quantum confinement obtained by semiconducting thermoelectric nanomaterial barrier layers of component A; and
c. carrier injection from barrier layer of component A into quantum well layer of component B to obtain different polarity thermoelectric heterostructure.

13. The heterostructure thermoelectric nanomaterial as claimed in claim 7, wherein chemical potential of the component B is lower than chemical potential of the component A.

14. The heterostructure thermoelectric nanomaterial as claimed in claim 7, wherein the component A is selected from a group comprising of: a p-type highly doped semiconducting nanomaterial and a n-type highly doped semiconducting nanomaterial having carrier concentration in the range of 10¹⁹ per cm³ to 10²¹ per cm³.

15. The heterostructure thermoelectric nanomaterial as claimed in claim 7, wherein sign of Seebeck Coefficient of heterostructure is determined by sign of Seebeck coefficient of the component A.

16. The heterostructure thermoelectric nanomaterial as claimed in claim 7, wherein enhancement in Seebeck coefficient and/or electrical conductivity is obtained for the heterostructure thermoelectric nanomaterial and wherein an enhancement in power factor is obtained due to quantum confinement in the heterostructure thermoelectric nanomaterial.

17. The heterostructure thermoelectric nanomaterial as claimed in claim 7, wherein reduction in thermal conductivity is obtained due to band offset values higher than typical phonon energies.

18. The heterostructure thermoelectric nanomaterial as claimed in claim 7, wherein a p-type networked heterostructure is obtained, wherein component B is selected from group comprising of: tellurium, zinc, bismuth to form a quantum well layer of component B, and wherein component A is selected as Sb₂₋ₓBiₓTe₃ to form a barrier layer of component A.

19. The heterostructure thermoelectric nanomaterial as claimed in claim 18, wherein the heterostructure thermoelectric nanomaterial is p-type tellurium/Sb₂₋ₓBiₓTe₃ heterostructure.

20. The heterostructure thermoelectric nanomaterial as claimed in claim 7, wherein a n-type networked heterostructure is obtained, wherein component B is selected from group comprising of: tellurium, zinc, bismuth to form a quantum well layer of component B, and wherein component A is selected as Bi₂Te₃₋ₓSeₓ to form a barrier layer of component A.

21. The heterostructure thermoelectric nanomaterial as claimed in claim 20, wherein the heterostructure thermoelectric nanomaterial is n-type tellurium/Bi₂Te₃₋ₓSeₓ heterostructure.

22. The heterostructure thermoelectric nanomaterial as claimed in claim 19, wherein a maximum value of p-type Seebeck Coefficient is 343.8 μV/K around room temperature for the p-type tellurium/Sb₂₋ₓBiₓTe₃ heterostructure.

23. The heterostructure thermoelectric nanomaterial as claimed in claim 19, wherein a maximum value of Electrical Conductivity is 6.5×10⁴ S/m around room temperature for the p-type tellurium/Sb₂₋ₓBiₓTe₃ heterostructure.

24. The heterostructure thermoelectric nanomaterial as claimed in claim 19, wherein a maximum value of Power Factor is 7.6 mW/mK² around room temperature for the p-type tellurium/Sb₂₋ₓBiₓTe₃ heterostructure.

25. The heterostructure thermoelectric nanomaterial as claimed in claim 19, wherein a minimum value of Thermal Conductivity is 1.06 W/m·K around room temperature for the p-type tellurium/Sb₂₋ₓBiₓTe₃ heterostructure.

26. The heterostructure thermoelectric nanomaterial as claimed in claim 19, wherein a maximum value of Figure of Merit (ZT) is 2.1 around room temperature for the p-type tellurium/Sb₂₋ₓBiₓTe₃ heterostructure.

27. The heterostructure thermoelectric nanomaterial as claimed in claim 19, wherein an average value of Figure of Merit (ZT) is 1.3 for a temperature range from room temperature to 250° C. for the p-type tellurium/Sb₂₋ₓBiₓTe₃ heterostructure.

28. The heterostructure thermoelectric nanomaterial as claimed in claim 19, wherein quantum confinement is confirmed by quantized plateaus in Hall resistance and correlated reducing longitudinal resistance peaks as a function of applied magnetic field at room temperature for the p-type tellurium/Sb₂₋ₓBiₓTe₃ heterostructure.

29. The heterostructure thermoelectric nanomaterial as claimed in claim 21, wherein a maximum value of n-type Seebeck Coefficient is (negative) 199.8μ V/K around room temperature for tellurium/Bi₂Te₃₋ₓSeₓ heterostructure.

30. The heterostructure thermoelectric nanomaterial as claimed in claim 21, wherein a maximum value of Electrical Conductivity is 1.5×10⁵ S/m around room temperature for the n-type tellurium/Bi₂Te₃₋ₓSeₓ heterostructure.

31. The heterostructure thermoelectric nanomaterial as claimed in claim 21, wherein a maximum value of Power Factor is 6.1 mW/mK² around room temperature for the n-type tellurium/Bi₂Te₃₋ₓSeₓ heterostructure.

32. The heterostructure thermoelectric nanomaterial as claimed in claim 21, wherein a minimum value of Thermal Conductivity is 0.71 W/m·K around room temperature for the n-type tellurium/Bi₂Te₃₋ₓSeₓ heterostructure.

33. The heterostructure thermoelectric nanomaterial as claimed in claim 21, wherein a maximum value of Figure of Merit (ZT) is 2.6 around room temperature for the n-type tellurium/Bi₂Te₃₋ₓSeₓ heterostructure.

34. The heterostructure thermoelectric nanomaterial as claimed in claim 21, wherein an average value of Figure of Merit (ZT) is 2.0 for a temperature range from room temperature to 250° C. for the n-type tellurium/Bi₂Te₃₋ₓSeₓ heterostructure.

35. The heterostructure thermoelectric nanomaterial as claimed in claim 21, wherein quantum confinement is confirmed by quantized plateaus in Hall resistances and correlated reducing longitudinal resistance peaks as a function of applied magnetic field at room temperature for the n-type tellurium/Bi₂Te₃₋ₓSeₓ heterostructure.
